(19) United States
(12) Patent Application Publication
(10) Pub. No.: US 2013/0140969 A1
(43) Pub. Date: Jun. 6, 2013

(54) COMPUTER CASE WITH SIDE PLATE HAVING CONVENIENT ATTACHING AND DETACHING MECHANISM

(71) Applicants: YUN-LUNG CHEN, Tu-Cheng (TW); CHUNG CHAI, Tu-Cheng (TW); XIAO-WEN DUAN, Wuhan City (CN); YI SHU, Wuhan City (CN)

(72) Inventors: YUN-LUNG CHEN, Tu-Cheng (TW); CHUNG CHAI, Tu-Cheng (TW); XIAO-WEN DUAN, Wuhan City (CN); YI SHU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/537,063

(22) Filed: Jun. 29, 2012

(30) Foreign Application Priority Data
Dec. 1, 2011 (CN) 201110392896.9

(51) Int. Cl. H05K 5/03

(52) U.S. Cl. 312/223.2

(57) ABSTRACT

An exemplary computer case includes a side plate, a rear cover and a knob. The side plate defines a recess. The rear cover defines a flange for abutting against the side plate when the side plate is attached to the computer case. The knob is partially and rotatably received in the recess. The knob includes a protruding member capable of being driven to rotate to a position where the protruding member and the side plate cooperatively sandwich the flange therebetween so that the side plate is attached to the computer case.

### BACKGROUND

1. Technical Field

The present disclosure relates to a computer case with a side plate, the side plate having a convenient mechanism for attaching and detaching the side plate to and from the computer case.

2. Description of Related Art

Computer cases are usually employed for receiving hard disk drives, floppy disk drives, optical disk drives and so on. However, the computer cases are usually assembled with bolts. In particular, bolts are used to perform a fixing function for a rear cover and a side plate of the computer case. Thus assembling and disassembling the computer case is a complex and time-consuming operation.

Therefore, it is desirable to provide a computer case to overcome the above-mentioned shortcomings.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a schematic, isometric view of a computer case in accordance with an exemplary embodiment of the present disclosure.

FIG. 2 is an exploded view of the computer case of FIG. 1.

FIG. 3 is an enlarged, exploded view of part of a side plate, a handle portion and a fixing portion of the computer case of FIG. 2.

FIG. 4 is a bottom view of the part of the side plate, the handle portion and the fixing portion of the computer case of FIG. 3.

FIG. 5 is a partly assembled view of the part of the side plate, the handle portion and the fixing portion of FIG. 4, showing the handle portion and the fixing portion in a position corresponding to a released state of the side plate.

FIG. 6 is a fully assembled view of FIG. 5, also showing the entire side plate in the released state.

FIG. 7 is similar to FIG. 5, but showing the handle portion and the fixing portion in a position corresponding to a fixed state of the side plate.

FIG. 8 is a fully assembled view of FIG. 7, also showing the entire side plate in the fixed state.

FIG. 9 is a cross sectional view of part of the computer case of FIG. 1, corresponding to line IX-IX thereof.

### DETAILED DESCRIPTION

Reference will now be made to the drawings to describe an exemplary embodiment of the present computer case.

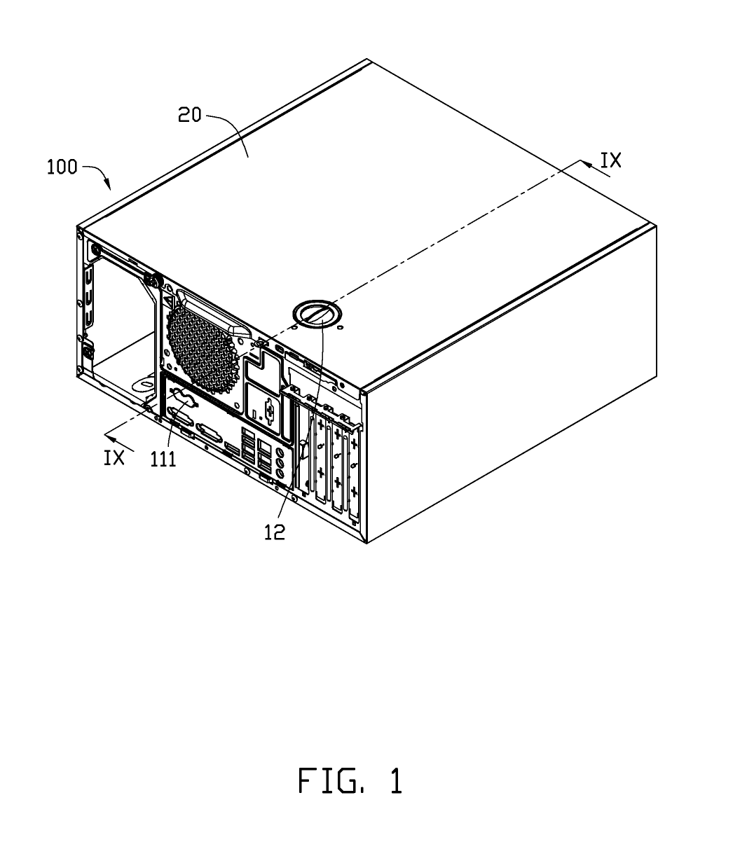

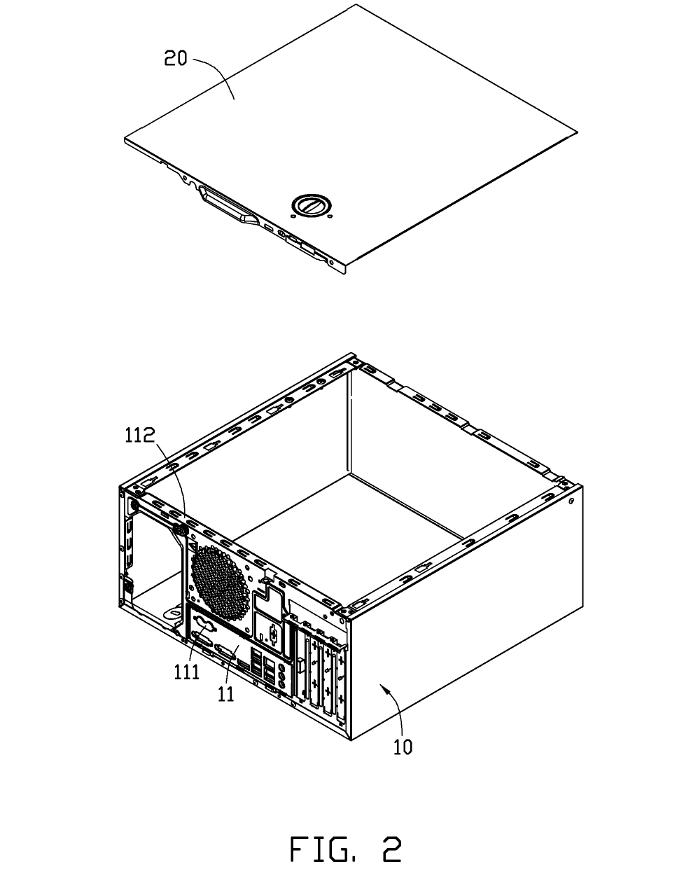

Referring to FIG. 1 and FIG. 2, a computer case 100, in this embodiment, includes a frame 10, a side plate 20, and a knob 12. In this embodiment, the knob 12 includes a handle portion 30 and a fixing portion 40 engaged with the handle portion 30.

Referring particularly to FIG. 2, the frame 10 has a hollow cuboid configuration, for receiving a hard disk drive, a floppy disk drive, an optical disk drive and so on. The frame 10 includes a rear cover 11 configured with a plurality of connection holes 111 therein, for cables to pass therethrough. The rear cover 11 has a flange 112 at a long side thereof. The flange 112 is a plate perpendicularly extending from a long side of a main body of the rear cover 11. The flange 112 is configured for abutting against the side plate 20.

The side plate 20 has a substantially rectangular shape. The side plate 20 is configured for covering one side of the frame 10.

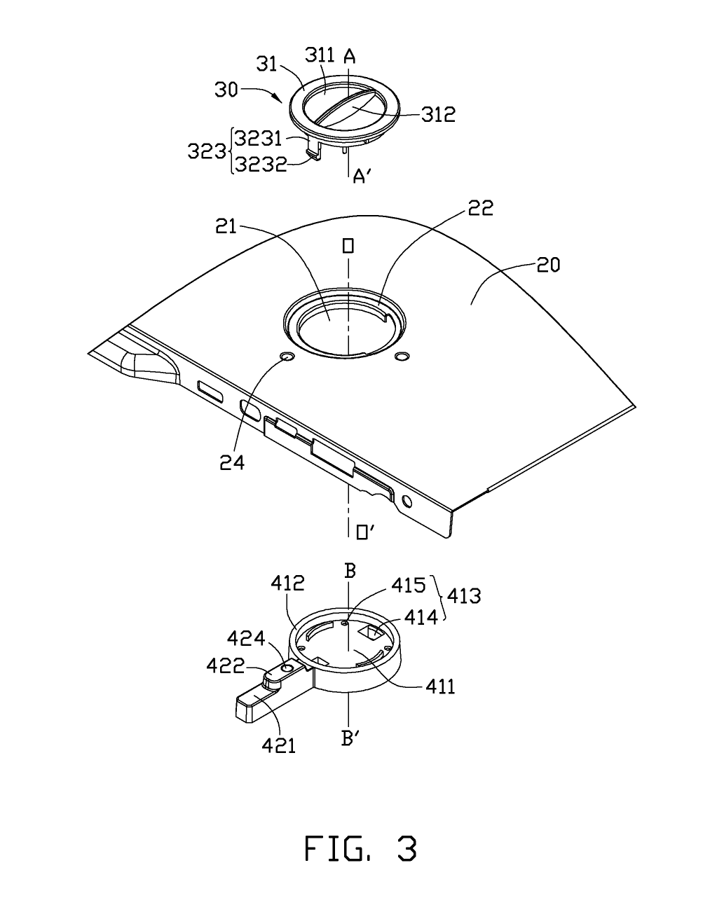

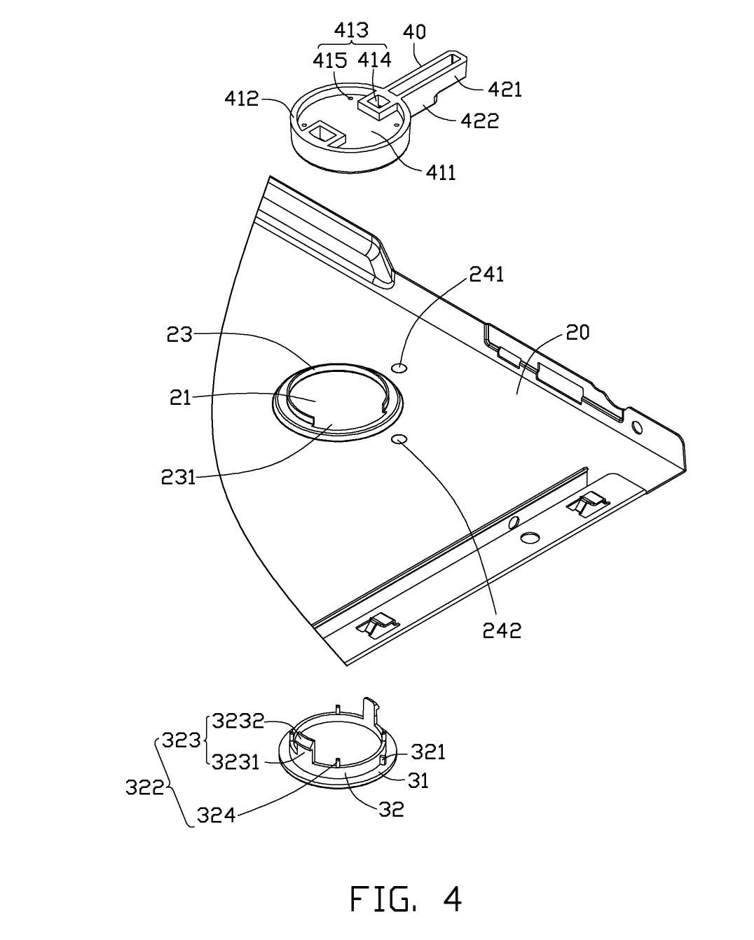

Referring to FIG. 3 and FIG. 4, the side plate 20 defines a recess 21 for receiving the handle portion 30. In this embodiment, the recess 21 has a cylindrical shape. The side plate 20 further defines an annular rim 22 at a bottom of the recess 21, and a collar portion 23 extending down from an inner edge of the annular rim 22.

The annular rim 22 is configured for supporting the handle portion 30 from below.

The collar portion 23 extends down parallel to a central axis OO′ of the recess 21, away from the side plate 20. In the illustrated embodiment, the collar portion 23 is annular-shaped, but has an arc-shaped cutout 231 defined therein. The cutout 231 has a length along a circumferential direction of the collar portion 23 which is smaller than a total circumference length of the collar portion 23.

The side plate 20 further defines at least one bump 24 at a periphery of the recess 21. The at least one bump 24 is configured for positioning the fixing portion 40. In this embodiment, there are two bumps 24, which are designated herein as a first bump 241 and a second bump 242. The first bump 241 is positioned adjacent to the rear cover 11. The second bump 242 is positioned corresponding to the cutout 231. An imaginary line interconnecting the first bump 241 and a nearest point on the central axis OO′ of the recess 21 is perpendicular to an imaginary line interconnecting the second bump 242 and the nearest point on the central axis OO′ of the recess 21.

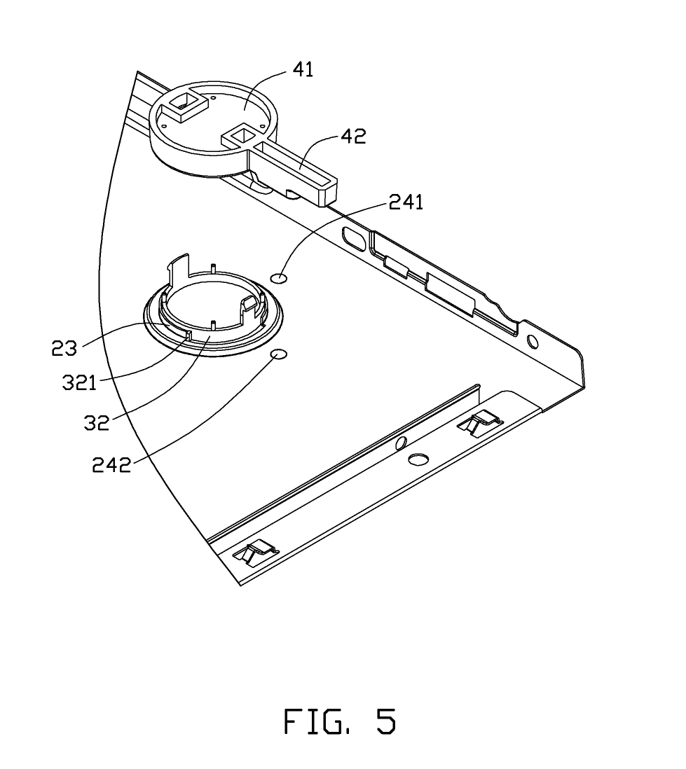

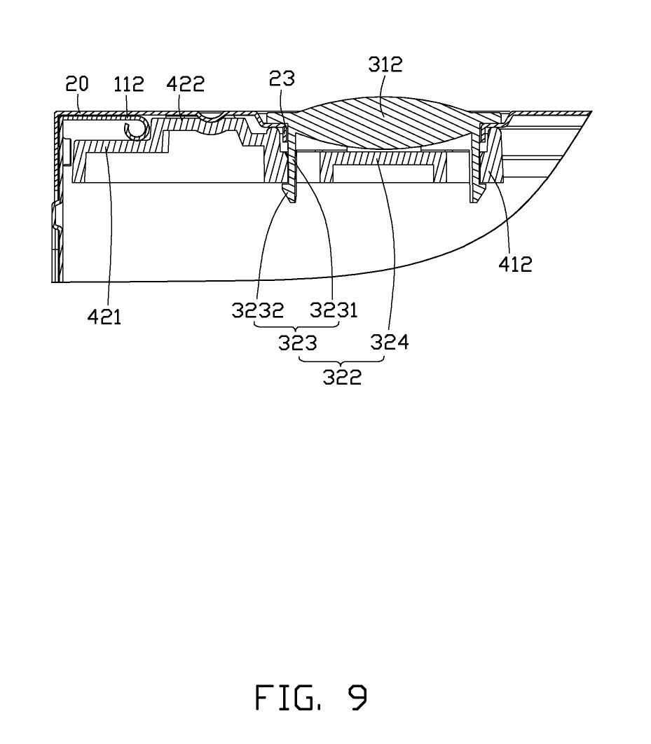

Referring to FIGS. 5-9, the handle portion 30 includes a first main body 31 and an annular wall 32. The annular wall 32 extends down from the first main body 31, parallel to a central axis AA′ of the handle portion 30 and towards the fixing portion 40.

The first main body 31 has a substantially round plate shape, with an outer diameter bigger than an inner diameter of the annular rim 22 and smaller than a diameter of the recess 21. As such, the first main body 31 can be rotatably received in the recess 21 and held by the annular rim 22. The first main body 31 further includes a depressed portion 311 defined in a middle thereof, and a turning handle 312 extending up from a middle of the depressed portion 311. Accordingly, users can drive the first main body 31 to rotate by gripping and turning the turning handle 312.

The annular wall 32 has an outer diameter smaller than the inner diameter of the annular rim 22, and thereby can penetrate through a central hole (not labeled) defined by the annular rim 22. The annular wall 32 has its outer surface abutting an inner edge of the annular rim 22. The annular wall 32 defines a limiting stopper 321 on the outer surface thereof. The limiting stopper 321 is located at a radial position of the handle portion 30 which corresponds to the cutout 231 of the side plate 20. As such, the limiting stopper 321 moves along the cutout 231 when the first main body 31 of the handle portion 30 is driven to rotate, and the rotation of the first main body 31 can be stopped when the limiting stopper 321 reaches an end of the cutout 231.

The annular wall 32 further includes a plurality of fixing posts 322 spaced apart from each other, for interconnecting the handle portion 30 with the fixing portion 40. In this embodiment, the annular wall 32 includes two first fixing posts 323 and four second fixing posts 324. Each first fixing post 323 includes a body 3231, and a hook 3232 outwardly extending from a distal (bottom) end of the body 3231 along a radial direction of the handle portion 30. Each second fixing post 324 has a cylindrical shape, with a length of the second fixing post 324 being smaller than that of each first fixing post 323 as measured parallel to the central axis AA′ of the handle portion 30.

The fixing portion 40 includes a second main body 41, and a protruding member 42 extending radially from the second main body 41.

The second main body 41 includes a supporting board 411, a plurality of through holes 413 defined in the supporting board 411, and two annular sidewalls 412 extending in mutually opposite directions parallel to a central axis BB′ of the second main body 41. That is, the two annular sidewalls 412 extend up and down from the supporting board 411, respectively.

The supporting board 411 has a substantially round shape. The through holes 413 include two first through holes 414 and four second through holes 415. Each first through hole 414 is generally rectangular. In the illustrated embodiment, one of the first through holes 414 is generally square. A radially outmost side of each first through hole 414 is curved, matching the curvature of a bottom one of the annular sidewalls 412. Each first through hole 414 is bounded not only by the supporting board 411, but also by a corresponding rectilinear collar 416 extending down from the supporting board 411. That is, the rectilinear collar 416 is located on a bottom surface of the supporting board 411, away from the side plate 20. The rectilinear collar 416 connects with an inner surface of the bottom annular sidewall 412. Each second through hole 415 has a cylindrical shape.

Each first fixing post 323 has its body 3231 penetrating through a corresponding one of the first through holes 414, with the hook 3232 snappingly fitted at a bottom of the rectilinear collar 416. In other words, the hook 3232 abuts against the rectilinear collar 416, and is thereby held in position at the bottom of the supporting board 411. At the same time, each second fixing post 324 extends into a corresponding second through hole 415. The second fixing post 324 may further protrude down from the second through hole 415 beyond the bottom surface of the supporting board 411.

The protruding member 42 includes a first extending portion 421 connected with the second main body 41, and a second extending portion 422 protruding up from the first extending portion 421. The second extending portion 422 extends from the first extending portion 421 in a direction parallel to the central axis BB′ of the second main body 41. The first extending portion 421 has a length as measured along a radial direction of the second main body 41 bigger than that of the second extending portion 422. The second extending portion 422 has an upper surface (not labeled) facing generally towards the handle portion 30 (i.e., facing away from the first extending portion 421). The second extending portion 422 defines a concave 424 in the upper surface thereof, for receiving a corresponding one of the first and second bumps 241, 242 of the side plate 20 at any one time.

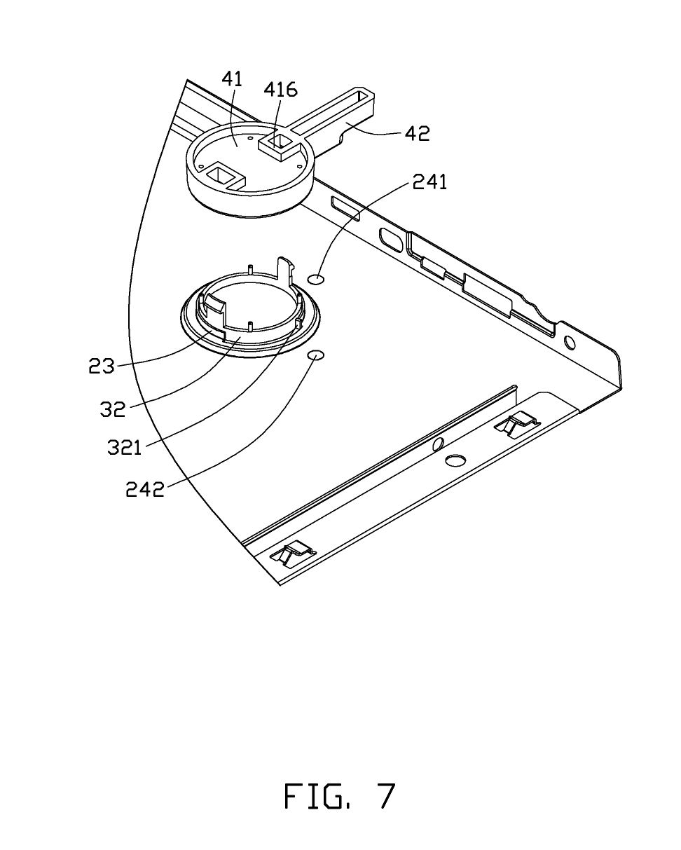

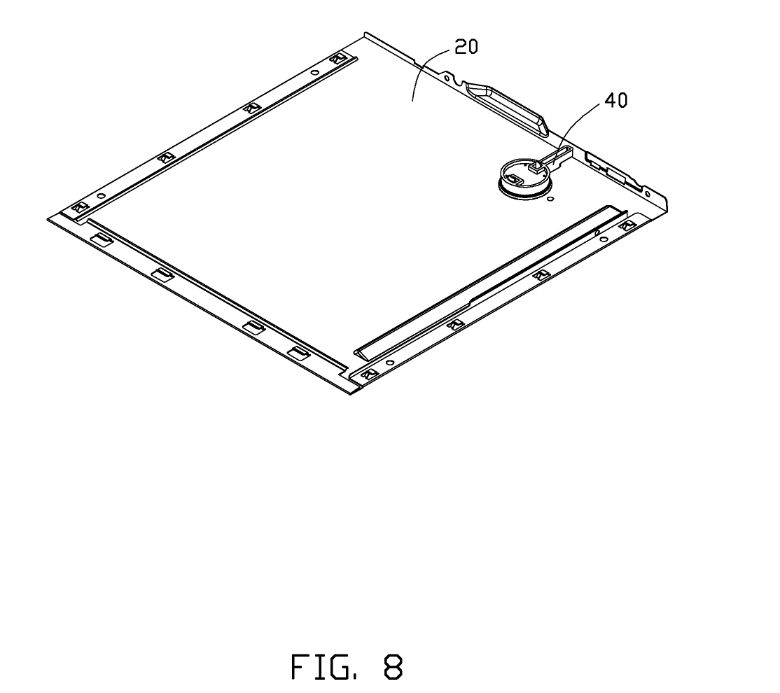

When attaching the side plate 20 to the frame 10, firstly, the side plate 20 is placed on the corresponding side of the frame 10. Then the protruding member 42 is driven, by the handle portion 30, to rotate about the central axis OO′ of the recess 21. Thus, the limiting stopper 321 moves towards a right end of the cutout 231 (as viewed in FIG. 7) and eventually abuts the collar portion 23 at the right end of the cutout 231. At this time, referring also to FIG. 8, the rotation of the protruding member 42 is stopped, with the protruding member 42 pointing to the rear cover 11, and with the concave 424 receiving the first bump 241 to hold the protruding member 42 in position. In this state, the first extending portion 421 and the side plate 20 cooperatively sandwich the flange 112 of the rear cover 11 therebetween. Accordingly, the side plate 20 is fixed onto the frame 10.

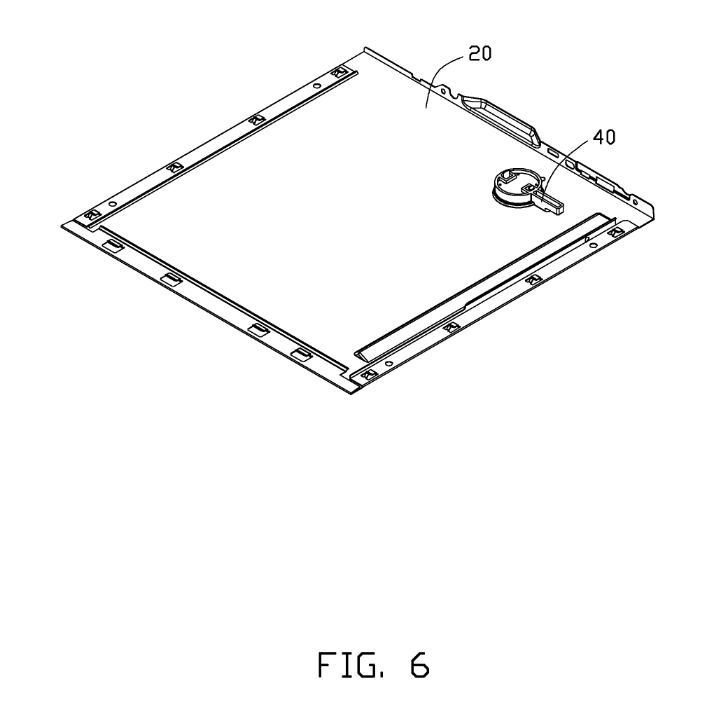

When detaching the side plate 20 from the frame 10, the protruding member 42 is firstly driven, by the handle portion 30, to rotate about the central axis OO′ of the recess 21. Thus, the limiting stopper 321 moves towards a left end of the cutout 231 (as viewed in FIG. 5) and abuts the collar portion 23 at the left end of the cutout 231. At this time, referring also to FIG. 6, the rotation of the protruding member 42 is stopped, with the protruding member 42 substantially parallel to the rear cover 11, and with the concave 424 receiving the second bump 242 to hold the protruding member 42 in position. In this state, the flange 112 of the rear cover 11 is released from the first extending portion 421 and the side plate 20. Accordingly, the side plate 20 is then easily removed from the frame 10.

Due to the fact that the side plate 20 can be attached to and detached from the frame 10 by rotating the knob 12, and without employing any bolts, the attaching and detaching operations are simplified and time-saving.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A computer case comprising:
a side plate defining a recess;
a rear cover defining a flange at a side thereof, the flange abutting against the side plate when the side plate is attached to the computer case; and
a knob partially and rotatably received in the recess, the knob comprising a protruding member capable of being driven to rotate to a position where the protruding member and the side plate cooperatively sandwich the flange therebetween so that the side plate is attached to the computer case.

2. The computer case of claim 1, wherein the recess has a cylindrical shape, and the side plate further defines an annular rim at a bottom of the recess, the annular rim supporting the knob.

3. The computer case of claim 2, wherein the side plate further defines a collar portion extending down from an inner edge of the annular rim parallel to an axial direction of the recess, and the collar portion has an arc-shaped cutout defined therein.

4. The computer case of claim 3, wherein the knob further comprises a handle portion and a fixing portion below and engaged with the handle portion, the handle portion is received in the recess, the side plate defines a bump at a periphery of the recess, the protruding member radially extends from a central first main body of the fixing portion, and the protruding member defines a concave for engagingly receiving the bump of the side plate when the protruding member and the side plate cooperatively sandwich the flange of the rear cover.

5. The computer case of claim 4, wherein the handle portion comprises a second main body, a depressed portion defined in a middle of the second main body, and a turning handle extending up from a middle of the depressed portion, the second main body having a substantially round plate shape with an outer diameter bigger than an inner diameter of the annular rim and smaller than a diameter of the recess.

6. The computer case of claim 5, wherein the handle portion further comprises an annular wall extending from the second main body parallel to an axis of the handle portion and towards the fixing portion, the annular wall defines a limiting stopper on an outer surface thereof, and the limiting stopper is located at a radial position of the handle portion and is movably received in the cutout.

7. The computer case of claim 6, wherein the annular wall comprises a plurality of fixing posts penetrating through the fixing portion and snappingly attached to a bottom of the fixing portion.

8. The computer case of claim 7, wherein the first main body of the fixing portion comprises a supporting board, a plurality of through holes defined in the supporting board, and two annular sidewalls extending in mutually opposite directions parallel to a central axis of the first main body, the plurality of fixing posts penetrating through the plurality of through holes.

9. The computer case of claim 8, wherein the protruding member comprises a first extending portion connected with the first main body of the fixing portion, and a second extending portion protruding up from the first extending portion parallel to the central axis of the first main body generally towards the handle portion, the first extending portion having a length as measured along a radial direction of the first main body bigger than that of the second extending portion, and the first extending portion and the side plate cooperatively sandwiching the flange of the rear cover when the protruding member is driven to rotate to the position where the protruding member and the side plate sandwich the flange therebetween.

10. The computer case of claim 9, wherein the second extending portion defines a surface facing generally towards the handle portion and away from the first extending portion, and the concave is defined in the surface of the second extending portion.

11. A computer case comprising:
a side plate;
a rear cover having a flange; and
a knob rotatably assembled on the side plate, the knob comprising a protruding member;
wherein the knob is rotatable between an attached position in which the protruding member of the knob is adjacent to the rear cover and the protruding member and the side plate cooperatively sandwich the flange therebetween, and a detached position in which the protruding member of the knob is away from the flange such that the side plate is liftable up from the flange.

12. The computer case of claim 11, wherein the side plate comprises a recess partially receiving the knob, the recess has a cylindrical shape, and the side plate further defines an annular rim at a bottom of the recess, the annular rim supporting the knob.

13. The computer case of claim 12, wherein the side plate further defines a collar portion extending down from an inner edge of the annular rim parallel to an axial direction of the recess, and the collar portion has an arc-shaped cutout defined therein.

14. The computer case of claim 13, wherein the knob further comprises a handle portion and a fixing portion below and engaged with the handle portion, the handle portion is received in the recess, the side plate defines a bump at a periphery of the recess, the protruding member radially extends from a central first main body of the fixing portion, and the protruding member defines a concave for engagingly receiving the bump of the side plate when the protruding member and the side plate cooperatively sandwich the flange of the rear cover.

15. The computer case of claim 14, wherein the handle portion comprises a second main body, a depressed portion defined in a middle of the second main body, and a turning handle extending up from a middle of the depressed portion, the second main body having a substantially round plate shape with an outer diameter bigger than an inner diameter of the annular rim and smaller than a diameter of the recess.

16. The computer case of claim 15, wherein the handle portion further comprises a annular wall extending from the second main body parallel to an axis of the handle portion and towards the fixing portion, the annular wall defines a limiting stopper on an outer surface thereof, and the limiting stopper is located at a radial position of the handle portion and is movably received in the cutout.

17. The computer case of claim 16, wherein the annular wall comprises a plurality of fixing posts penetrating through the fixing portion and snappingly attached to a bottom of the fixing portion.

18. The computer case of claim 17, wherein the first main body of the fixing portion comprises a supporting board, a plurality of through holes defined in the supporting board, and two annular sidewalls extending in mutually opposite directions parallel to a central axis of the first main body, the plurality of fixing posts penetrating through the plurality of through holes.

19. The computer case of claim 18, wherein the protruding member comprises a first extending portion connected with the first main body of the fixing portion, and a second extending portion protruding up from the first extending portion parallel to the central axis of the first main body generally towards the handle portion, the first extending portion having a length as measured along a radial direction of the second main body bigger than that of the second extending portion, and the first extending portion and the side plate cooperatively sandwiching the flange of the rear cover when the protruding member is driven to rotate to the position where the protruding member and the side plate sandwich the flange therebetween.

20. The computer case of claim 19, wherein the second extending portion defines a surface facing generally towards the handle portion and away from the first extending portion, and the concave is defined in the surface of the second extending portion.
